(19) United States
(12) Patent Application Publication
(10) Pub. No.: US 2016/0189990 A1
(43) Pub. Date: Jun. 30, 2016

(54) LASER CRYSTALLZIATION SYSTEM AND METHOD OF CONTROLLING CRYSTALLIZATION ENERGY THEREIN

(71) Applicant: Shenzhen China Star Optoelectronics Technology Co. Ltd., Shenzhen, Guangdong (CN)

(72) Inventors: Zhigang WANG, Shenzhen, Guangdong (CN); Zijian LI, Shenzhen, Guangdong (CN); Lijuan TANG, Shenzhen, Guangdong (CN); Yong LI, Shenzhen, Guangdong (CN)

(73) Assignee: Shenzhen China Star Optoelectronics Technology Co. Ltd., Shenzhen, Guangdong (CN)

(21) Appl. No.: 14/433,638

(22) PCT Filed: Jan. 6, 2015
(86) PCT No.: PCT/CN2015/070185

§ 371 Date: Apr. 3, 2015

(30) Foreign Application Priority Data
Dec. 29, 2014 (CN) 2014108370079

(51) Int. Cl. H01L 21/67; H01L 27/12; H01L 21/02; H01L 21/324; H01S 3/225; G03F 1/50

(52) U.S. Cl. CPC H01L 21/67115; H01S 3/225; G03F 1/50; H01L 21/02675; H01L 21/324; H01L 27/1288; H01L 27/1285

(57) ABSTRACT

A laser crystallization system and a method of controlling crystallization energy therein are disclosed. The laser crystallization system comprises: a Mura monitor device, used for monitoring the real-time Mura status during the crystallization process; a host station, connected with the Mura monitor device, used for determining the real-time level of the real-time Mura status acquiring from the Mura monitoring device, and generating crystallization energy control order based on the real time level; a crystallization device, connected with the host station, for carrying out the crystallization energy control order generated from the host station to control the outputting crystallization energy. The Mura monitoring device is used to monitor the Mura status online in real-time, and the crystallization energy outputted by the crystallization device is controlled according to the real-time Mura status. The present invention can achieve the effective monitoring of the Mura status of the product, further to control the corresponding crystallization energy. Comparing with the artificial way, the instant embodiment enhances the working efficiency, and is able to ensure the accuracy and control online to ensure the product yield.

### FIELD OF THE INVENTION

The present invention relates to a technical field of crystallization manufacturing; in particular, to a method of controlling crystallization energy and a laser crystallization system using the method of controlling crystallization energy.

### BACKGROUND OF THE INVENTION

As is known to all, a liquid crystal display has some advantages such as a slim shape, low power consumption, good resolution, no radiation and anti-electromagnetic interference, so it has been widely used on cell phones, personal digital assistants (PDAs), laptops, flat displays and some information appliances. However, with the user requirements for the display to enhance the visual experience, coupled with the application of new technologies continues to expand, so the higher-quality, low-cost high-resolution flat-panel displays and having become the future of display technology trends, but also created a new display technology made the driving force. The technology of low temperature polysilicon thin film transistors (LTPS TFT) is an important technological breakthrough which achieves the above goals.

Most of the general low-temperature polysilicon process using an excimer laser annealing (Excimer LaserAnnealing, ELA) technology, namely the use of the excimer laser as a heat source to convert the amorphous structure of the polysilicon structure. When the excimer laser, after the optical projection system, will produce a uniform laser beam energy distribution, and projected to the amorphous silicon film deposited on the substrate so that the absorption energy of the excimer laser and the amorphous silicon film is transformed into a polysilicon recrystallization structure. Because of the above process is completed in the following 600° C., generally a glass substrate or a plastic substrate, etc. can apply, and therefore more to expand the application range of low-temperature polysilicon thin-film transistor liquid crystal display.

As described above, the current in the low-temperature polysilicon thin film transistor liquid crystal display production, is irradiated with an excimer laser beam scanning the substrate, whereby the substrate is pre-deposited amorphous silicon is converted to polysilicon structure. After the formation of excimer laser light quality of the polysilicon structure of the substrate surface will directly affect the characteristics of various components, the crystalline state and the quality of the polycrystalline silicon is mainly influenced by the binomial factors, one for the film thickness of the amorphous silicon substrate surface, one for energy density. Amorphous or crystalline state in which the film thickness varies with temperature polysilicon thin film transistor liquid crystal display design, or the difference between the amorphous silicon coating process reaction conditions, excimer laser annealing process of each batch of the substrate surface may vary must be chosen, thus making for excimer laser annealing process appropriate excimer laser energy density, otherwise it would be poorly crystalline polysilicon substrate surface state. Further, since the principle of the excimer laser gas is sealed in a closed chamber and excite the gas to produce electricity using excimer laser light, depending on the use condition of the excimer laser is typically about 10 hours That experience must be refilled fresh air, and the quasi-molecular laser energy density will decay with time, and therefore its energy density is difficult to control. Based on the above-mentioned limitations imposed by the excimer laser, the excimer laser light during the process, even if a preset optimum energy density, the actual energy density of the excimer laser is often vary due to fading with a pre-set value, and the impact polysilicon crystalline state.

However, in the conventional art of the crystallization process, the Mura status has to be controlled. The conventional method investigates the Mura status by using the off-line macroscopic and microscopic inspection machine defect inspection machine (MAC/MIC), and then makes sure of the best range of the off-line crystallization energy. The method has to turn off the machine, and adjust it off-line so the host station has larger work influence, and it spends thirty minutes one time. Additionally, the method cannot be changed on time, and it results in the loss of the product yield. Further, the investigation method mainly uses human eyes, causes misjudging and has human factors to affect adjustments.

It is not difficult to see that using the above investigation method cannot monitor the Mura status of the product efficiently even though there is not good crystallization condition of polysilicon on the substrate, further not to control the corresponding crystallization energy with the low work efficiency and accuracy.

### SUMMARY OF THE INVENTION

In light of this, the present invention provides a method of controlling crystallization energy of a laser crystallization system to solve the problem in the conventional art, which cannot efficiently monitor the Mura status of the product, further to control the corresponding crystallization energy with some technical weaknesses of the low work efficiency and bad accuracy.

In order to solve the above technical problems, the present invention provides a laser crystallization system, wherein the laser crystallization system comprises: a Mura monitor device, used for monitoring the real-time Mura status during the crystallization process; a host station, connected with the Mura monitor device, used for determining the real-time level of the real-time Mura status acquiring from the Mura monitoring device, and generating crystallization energy control order based on the real time level; a crystallization device, connected with the host station, for carrying out the crystallization energy control order generated from the host station to control the outputting crystallization energy.

Further, the host station comprises a memory module, for storing a correspondence table relative to the real-time Mura status and the crystallization energy control order; and a determining module, for searching a corresponding level of the crystallization energy control order from the memory module based on the real-time Mura status acquired from the Mura monitoring device.

Further, the determining module is used for determining whether the real-time level of the real-time Mura status reaches a preset threshold value, and when determining the real-time level of the real-time Mura status is lower than the preset threshold value, the crystallization energy control order is not performed such that the crystallization device maintains an original crystallization energy outputting level.

In order to solve the above technical problem, the present invention further provides a method of controlling crystallization energy of a laser crystallization system characterized in that the method of controlling crystallization energy comprises: monitoring a real-time Mura status by a Mura monitoring device during a crystallization process; determining a real-time level of the real-time Mura status by the Mura monitoring device, and generating a crystallization energy control order based on the real-time level; performing the crystallization energy control order to control the outputting crystallization energy.

Further, the method of controlling crystallization energy comprises: storing a correspondence table relative to the real-time Mura status and the crystallization energy control order; the step of generating the crystallization energy control order based on the real-time level, specifically comprises: looking for the corresponding crystallization energy control order from the correspondence table based on the real-time Mura status acquired from the Mura monitoring device.

Further, the step of determining a real-time level of the real-time Mura status by the Mura monitoring device further comprises: determining whether the real-time level of the real-time Mura status reaches a preset threshold value, and when determining the real-time level of the real-time Mura status is lower than the preset threshold value, the crystallization energy control order is not performed such that the crystallization system maintains an original crystallization energy outputting level.

Through the above technical solution, the advantage of the present invention is to monitor the Mura status online in real-time by using the Mura monitoring device, and the crystallization energy outputted by the crystallization device is controlled according to the real-time Mura status. It is not difficult to find out that the present invention can achieve the effective monitoring of the Mura status of the product, further to control the corresponding crystallization energy. Comparing with the artificial way, the instant embodiment enhances the working efficiency, and is able to ensure the accuracy and online control with high the product yield.

### BRIEF DESCRIPTION OF THE DRAWINGS

In order to illustrate the embodiment of the technical solution of the present embodiment of the invention more clearly, embodiments will be described in the following figures for the embodiment to be used in the simple introduction, it is obvious, the following description of the accompanying drawings are only some of the invention embodiment, with respect to those of ordinary skill in view, in the premise without creative efforts can also obtain other drawings according to these drawings.

FIG. 1 is a functional block diagram of an embodiment based on a laser crystallization system of the present invention;

FIG. 2 is a functional block diagram of an embodiment of a host station shown in FIG. 1;

FIG. 3 is a flow chart of an embodiment of a method of controlling crystallization energy of the present invention.

### DETAILED DESCRIPTION OF THE PREFERRED EMBODIMENTS

In order to better illustrate the prior art embodiment or embodiments of the present invention, the technical solution, embodiments of the following figures will be described in the embodiments or the prior art are briefly introduced needed, obviously, the following description of the attached diagram is merely an embodiment of the present invention, and persons of ordinary skill in this art, in the premise without creative efforts can also obtain other drawings based on these drawings.

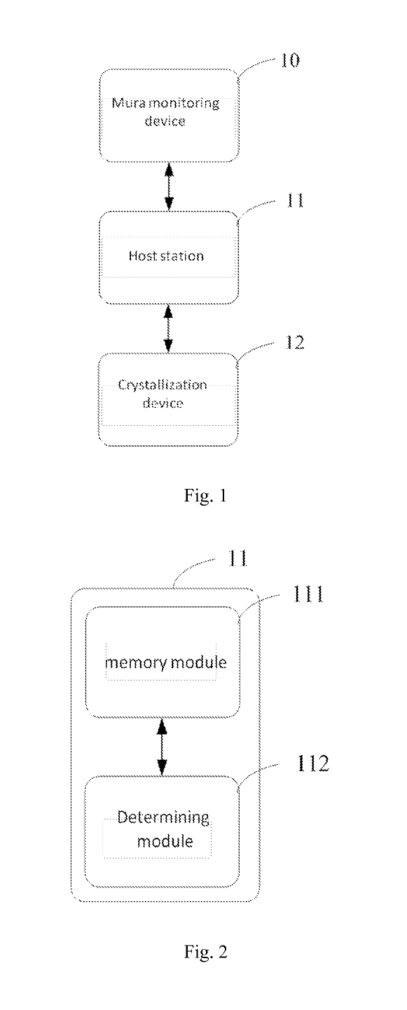

Please refer to FIG. 1. FIG. 1 is a functional block diagram of an embodiment based on a laser crystallization system of the present invention. The laser crystallization system of the present invention comprises a Mura monitoring device 10, a host station 11 and a crystallization device 12.

In the instant embodiment, a Mura monitoring device 10 is used for monitoring a real-time Mura status during the crystallization process.

Where, the host station 11 connects with the Mura monitoring device 10 for determining a real-time level of the real-time Mura status acquiring from the Mura monitoring device 10 and generating a crystallization energy control order based on the real time level.

The crystallization device 12 of the instant embodiment connects it the host station 11 for performing the crystallization energy control order to control outputting crystallization energy.

Please further refer to FIG. 2. FIG. 2 is a functional block diagram of an embodiment of a host station shown in FIG. 1, where the host station 11 comprises a memory module 111 and a determining module 112.

In the instant embodiment, the memory module 111 is used for storing a correspondence table relative to real-time Mura status and the crystallization energy control order.

Correspondingly, the determining module 112 is used for searching a corresponding level of the crystallization energy control order from the memory module based on the real-time Mura status acquired from the Mura monitoring device.

It is not difficult to understand that the instant embodiment enhance the work efficiency and performance of the host station 11 by the way of setting the correspondence table.

It should be noted that the determining module 112 is further used for determining whether the real-time level of the real-time Mura status reaches a present threshold value, and when determining the real-time level of the real-time Mura status is lower than the preset threshold value, the crystallization energy control order is not performed such that the crystallization system maintains an original crystallization energy outputting level, where the instant embodiment can prevent from searching the correspondence table repeatedly and frequently. Moreover, the instant embodiment compares the investigated real-time Mura status with the preset threshold value, and directly determines if the crystallization energy needs to be controlled to enhance the working efficiency.

Otherwise, in other embodiments, the Mura monitoring device 10 could comprises an excimer laser annealing device, a source generating device, an image receiver and so on. The excimer laser annealing device generates an excimer laser and illustrates a substrate by linear scanning to transform a crystalline state of a silicon thin film from an amorphous silicon structure into a polysilicon structure

The instant embodiment uses the Mura monitoring device 10 to monitor the Mura status online in real-time, and the crystallization energy outputted by the crystallization device 12 is controlled according to the real-time Mura status. It is not difficult to find out that the present invention can achieve the effective monitoring of the Mura status of the product, further to control the corresponding crystallization energy. Comparing with the artificial way, the instant embodiment enhances the working efficiency, and is able to ensure the accuracy and control online to ensure the product yield.

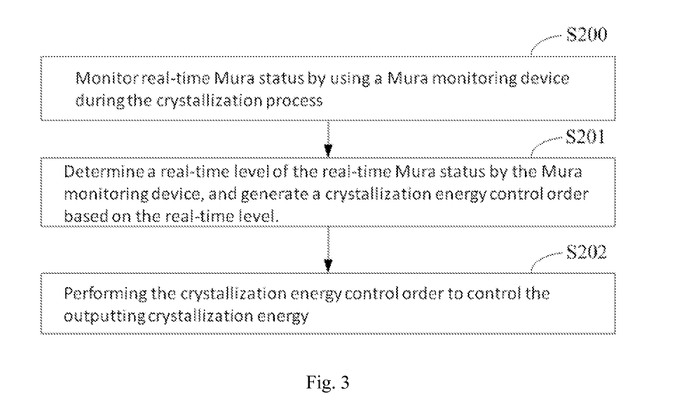

Please see FIG. 1, FIG. 2 and FIG. 3 together. FIG. 3 is a flow chart of an embodiment of a method of controlling crystallization energy of the present invention. The method of controlling crystallization energy of the instant invention comprises the following steps.

Step S200: monitor real-time Mura status by using a Mura monitoring device during the crystallization process.

In the step S200, the instant embodiment can adopt the Mura monitoring device to on-line monitor, and the Mura monitoring device connects with an ELA machine.

Step S201: determine a real-time level of the real-time Mura status by the Mura monitoring device, and generate a crystallization energy control order based on the real-time level.

In Step S201, the instant embodiment can further store a correspondence table relative to the real-time Mura status and the crystallization energy control order; then look for the corresponding crystallization energy control order from the correspondence table based on the real-time Mura status acquired from the Mura monitoring device when the real-time Mura status generates the crystallization energy control order. It is not difficult to understand that the instant embodiment can enhance the working efficiency and performance of the host station 11 by the way of setting the correspondence table.

It has to explain that when determining a real-time level of the real-time Mura status by the Mura monitoring device, the instant embodiment can further determine whether the real-time level of the real-time Mura status reaches a preset threshold value, and when determining the real-time level of the real-time Mura status is lower than the preset threshold value, the crystallization energy control order is not performed such that the crystallization system maintains an original crystallization energy outputting level. Through this way, the instant embodiment can prevent from searching the correspondence table repeatedly, and determine directly if the crystallization energy has to be controlled to enhance the work efficiency by comparing the investigated real-time Mura status and the preset threshold value in advance.

Step S202: performing the crystallization energy control order to control the outputting crystallization energy.

The instant embodiment uses the Mura monitoring device to monitor the Mura status online in real-time, and the crystallization energy outputted by the crystallization device is controlled according to the real-time Mura status. It is not difficult to find out that the present invention can achieve the effective monitoring of the Mura status of the product, further to control the corresponding crystallization energy. Comparing with the artificial way, the instant embodiment enhances the working efficiency, and is able to ensure the accuracy and control online to ensure the product yield.

The above-described embodiments of the invention only, and not to limit the patent scope of the present invention, therefore, the use of all contents of the specification and drawings of the present invention is made equivalent structures or equivalent conversion process, either directly or indirectly in the other the relevant art, are included within the same reason the patent scope of the present invention.

What is claimed is:

1. A laser crystallization system, wherein the laser crystallization system comprises:
a Mura monitoring device for monitoring real-time Mura status in a crystallization process, the Mura monitoring device includes an excimer laser annealing device, a source generating device and an image receiver, wherein the excimer laser annealing device generates an excimer laser and illustrates a substrate by linear scanning to transform a crystalline state of a silicon thin film from an amorphous silicon structure into a polysilicon structure;
a host station, connected with the Mura monitoring device, for determining a real time level acquired from the Mura monitoring device, and generating crystallization energy control order based on the real time level;
a crystallization device, connected with the host station, for carrying out the crystallization energy control order generated from the host station to control the outputting crystallization energy.

2. A laser crystallization system, wherein the laser crystallization system comprises:
a Mura monitoring device for monitoring real-time Mura status in a crystallization process;
a host station, connected with the Mura monitoring device, for determining a real time level of the real-time Mura status acquired from the Mura monitoring device, and generating a crystallization energy control order based on the real time level;
a crystallization device, connected with the host station, for carrying out the crystallization energy control order generated from the host station to control an outputting crystallization energy.

3. The laser crystallization system as claimed in claim 2, wherein the host station comprises:
a memory module, for storing a correspondence table relative to the real-time Mura status and the crystallization energy control order;
a determining module, for searching a corresponding level of the crystallization energy control order from the memory module based on the real-time Mura status acquired from the Mura monitoring device.

4. The laser crystallization system as claimed in claim 3, wherein the determining module is further used for determining whether the real-time level of the real-time Mura status reaches a preset threshold value, and when determining the real-time level of the real-time Mura status is lower than the preset threshold value, the crystallization energy control order is not performed such that the crystallization device maintains an original crystallization energy outputting level.

5. A method of controlling crystallization energy of a laser crystallization system, wherein the method of controlling crystallization energy comprises:
monitoring a real-time Mura status by a Mura monitoring device during a crystallization process;
determining a real-time level of the real-time Mura status by the Mura monitoring device, and generating a crystallization energy control order based on the real-time level;
performing the crystallization energy control order to control the outputting crystallization energy.

6. The method of controlling crystallization energy as claimed as claim 5, wherein the method of controlling crystallization energy further comprises:
storing a correspondence table relative to the real-time Mura status and the crystallization energy control order;
the step of generating the crystallization energy control order based on the real-time level, specifically comprises:
looking for the corresponding crystallization energy control order from the correspondence table based on the real-time Mura status acquired from the Mura monitoring device.

7. The method of controlling crystallization energy as claimed as claim 6, wherein the step of determining a real-time level of the real-time Mura status by the Mura monitoring device further comprises:
determining whether the real-time level of the real-time Mura status reaches a preset threshold value, and when determining the real-time level of the real-time Mura status is lower than the preset threshold value, the crystallization energy control order is not performed such that the crystallization system maintains an original crystallization energy outputting level.

8. The photo mask as claimed in claim 7, wherein the semi-transparent gray scale mask area is disposed at opposite sides of the light shielding region.
